(19) United States
(12) Patent Application Publication
(10) Pub. No.: US 2020/0120837 A1
(43) Pub. Date: Apr. 16, 2020

(54) FLUID COOLED POWER ELECTRONIC ASSEMBLY

(71) Applicant: KSR IP Holdings, LLC, Wilmington, DE (US)

(72) Inventors: Eric Hustedt, Halifax (CA); Dan O'Neill, Chatham (CA); Nicholas Alain Doucet, Lake Echo (CA)

(21) Appl. No.: 16/601,016

(22) Filed: Oct. 14, 2019

Related U.S. Application Data
(60) Provisional application No. 62/745,012, filed on Oct. 12, 2018.

(51) Int. Cl. H05K 7/20; H01L 23/473; F02N 11/04

(52) U.S. Cl. CPC H05K 7/20927; F02N 11/04; H01L 23/473; H05K 7/20281

(57) ABSTRACT

A power electronic assembly is provided. The power electronic assembly includes a housing, a plurality of modules, a first circuit board, a second circuit board, and a cooling structure. The housing has a lower wall and an outer wall that circumferential surrounds the lower wall. The lower wall has an interior surface and an opposite exterior surface. The plurality of modules are in contact with the interior surface of the lower wall. The lower wall is a heatsink configured to assist in removing heat generated by the plurality of modules. The first circuit board is positioned above the plurality of modules in the system vertical direction and communicatively coupled to the plurality of modules. The second circuit board is positioned between the plurality of modules and the first printed circuit board. The cooling structure is coupled to the exterior surface of the lower wall to cool the heatsink.

### CROSS REFERENCE To RELATED APPLICATIONS

This Application claims priority of U.S. Provisional Application Ser. No. 62/745,012 filed on Oct. 12, 2018, the content of which is incorporated herein in its entirety.

### TECHNICAL FIELD

The present disclosure generally relates to converter circuits mounted to cooling structures and, more specifically, to converter circuits mounted to cooling structures having integrated fluid channel systems extending within the cooling structures.

### BACKGROUND

Belt starter generator machines generally have an inverter mounted to one end of the machine. The belt starter generator machines are generally designed to operate at extremely hot temperatures with the winding of the machine having temperatures near 220 degrees Celsius. As such, belt starter generator machines generally include at least a pair of fans disposed at opposite ends to cool the machine. Generally, one fan is disposed near the invertor side and the other fan is disposed on the opposite end. Further, the machine has an exhaust outlet near the fan to exhaust the much hotter air from within the machine. However, due to the close proximity of the exhaust outlet to an air inlet of the inverter, many times an air recirculation path for the air inlet of the inverter becomes mixed with the much hotter machine exhaust air.

Accordingly, a need exists to limit the amount of recirculation of the exhaust air entering the recirculation path and the air inlet of the inverter.

### SUMMARY

A power electronic assembly is provided. The power electronic assembly includes a housing, a plurality of modules, a first circuit board, a second circuit board, and a cooling structure. The housing has a lower wall and an outer wall that circumferentially surrounds the lower wall. The lower wall has an interior surface and an opposite exterior surface. The plurality of modules are in contact with the interior surface of the lower wall. The lower wall is a heatsink configured to assist in removing heat generated by the plurality of modules. The first circuit board is positioned above the plurality of modules in the system vertical direction and communicatively coupled to the plurality of modules. The second circuit board is positioned between the plurality of modules and the first printed circuit board. The cooling structure is coupled to the exterior surface of the lower wall to cool the heatsink.

A power electronic assembly is provided. The power electronic assembly includes a housing, a plurality of modules, a first circuit board and a battery stud assembly. The housing has a lower wall and an outer wall that circumferentially surrounds the lower wall. The lower wall has an interior surface and an opposite exterior surface. The plurality of modules are in contact with the interior surface of the lower wall. The first circuit board is positioned above the plurality of modules in the system vertical direction and communicatively coupled to the plurality of modules. The battery stud assembly extends through a portion of the outer wall and is communicatively coupled to the first circuit board. The battery stud assembly includes a pair of posts, a pair of straps and a common filter. The pair of straps are independently coupled to a respective one of the pair of posts. The common filter is coupled to each of the pair of straps. Each one of the pair of straps and the common filter are configured to eliminate electro-magnetic interference.

A power electronic assembly is provided. The power electronic assembly includes a housing, a plurality of modules, a first circuit board, a second circuit board, and a cooling tube. The housing has a lower wall and a continuous outer wall that circumferential surrounds the lower wall. The lower wall has an interior surface and an opposite exterior surface. The plurality of modules are in contact with the interior surface of the lower wall. The first circuit board is positioned above the plurality of modules in the system vertical direction and communicatively coupled to the plurality of modules. The second circuit board is positioned between the plurality of modules and the first printed circuit board. The cooling tube includes a fluid inlet and a fluid outlet. The fluid inlet is for receiving a cooling fluid into the cooling tube and the fluid outlet is for removing the cooling fluid from the cooling tube. The cooling fluid removes heat generated by the plurality of modules.

### BRIEF DESCRIPTION OF THE DRAWINGS

The embodiments set forth in the drawings are illustrative and exemplary in nature and not intended to limit the subject matter defined by the claims. The following detailed description of the illustrative embodiments can be understood when read in conjunction with the following drawings, where like structure is indicated with like reference numerals and in which:

FIG. 1 schematically depicts a perspective view of a first example power electronic assembly, according to one or more embodiments shown or described herein;

FIG. 2A schematically depicts a bottom view of the first example power electronic assembly of FIG. 1, according to one or more embodiments shown or described herein;

FIG. 2B schematically depicts a partial bottom view of the first example power electronic assembly of FIG. 1, according to one or more embodiments shown or described herein;

FIG. 3 schematically depicts a perspective view of the first example power electronic assembly of FIG. 1 without a cover, according to one or more embodiments shown or described herein;

FIG. 4 schematically depicts a cross-sectional view of the first example power electronic assembly of FIG. 1 taken from line 4-4, according to one or more embodiments shown or described herein;

FIG. 5 schematically depicts a perspective view of a plurality of power modules and a second circuit board of the first example power electronic assembly of FIG. 1, according to one or more embodiments shown or described herein;

FIG. 6 schematically depicts an isolated view of one of the plurality of power modules of the first example power electronic assembly of FIG. 5, according to one or more embodiments shown or described herein;

FIG. 7A schematically depicts an isolated view of a battery stud assembly of the first example power electronic assembly of FIG. 1 with a pair of studs in a first and second example configuration, according to one or more embodiments shown or described herein;

FIG. 7B schematically depicts an isolated view of a battery stud assembly of the first example power electronic assembly of FIG. 7A with the pair of studs in a third and fourth example configuration, according to one or more embodiments shown or described herein;

FIG. 8 schematically depicts a perspective view of a second example power electronic assembly, according to one or more embodiments shown or described herein;

FIG. 9 schematically depicts a perspective bottom view of the second power electronic assembly of FIG. 8, according to one or more embodiments shown or described herein;

FIG. 10 schematically depicts a bottom view of the power electronic assembly of FIG. 8 without a guide plate, according to one or more embodiments shown or described herein;

FIG. 11 schematically depicts a cross-sectional view of the power electronic assembly of FIG. 8 and the fluid flow path taken from line 11-11 according to one or more embodiments shown or described herein;

FIG. 12A schematically depicts an isolated view of a battery stud assembly of the power electronic assembly of FIG. 8 with a pair of studs in a first example configuration, according to one or more embodiments shown or described herein;

FIG. 12B schematically depicts an isolated view of a battery stud assembly of the power electronic assembly of FIG. 8 with the pair of studs in a second example configurations according to one or more embodiments shown or described herein;

FIG. 12C schematically depicts an isolated view of a battery stud assembly of the power electronic assembly of FIG. 8 with a pair of studs in a third example configuration, according to one or more embodiments shown or described herein; and

FIG. 13 schematically depicts an air temperature surrounding the power electronic assembly of FIG. 8, according to one or more embodiments shown or described herein.

### DETAILED DESCRIPTION

Embodiments described herein are related to a power electronic assembly that includes a cooling structure. The power electronic assembly may be a five-phase compact inverter assembly for a vehicle belt starter generator machine. The power electronic assembly includes a lower wall that has an interior surface and an exterior surface. A continuous outer wall circumferentially surrounds the lower wall. The power electronic assembly includes a plurality of half-bridge power modules in contact with the interior surface of the lower wall. The power electronic assembly further includes a first circuit board and a second circuit board. The first circuit board is positioned above the plurality of modules in a system vertical direction and is communicatively coupled to the plurality of modules. The second circuit board is positioned between the plurality of modules and the first printed circuit board and is in contact with interior surface of the lower wall and communicatively coupled to the plurality of modules.

In embodiments, the cooling structure is a cooling tube coupled to the exterior surface of the housing and positioned directly below each one of the plurality of power modules such that the lower wall is a heatsink configured to assist in removing heat generated by the plurality of modules. The cooling tube includes a fluid inlet and a fluid outlet. The fluid inlet is configured for receiving a cooling fluid into the cooling tube and the fluid outlet is for removing the cooling fluid from the cooling tube. The cooling fluid removes heat generated by the plurality of modules.

Further, in this embodiment, the power electronic assembly includes a battery stud assembly extending through a portion of the continuous outer wall and communicatively coupled to the first and second circuit boards. A field connector extends through a portion of the continuous outer wall and is communicatively coupled to the first circuit board. A signal connector extends through a portion of the continuous outer wall and communicatively coupled to the first circuit board. The battery stud assembly includes a pair of posts, a common electro-magnetic interference filter core coupled to each of the pair of posts. Each post is independently coupled to an electro-magnetic interference strap such that each strap and the common electro-magnetic interference filter core are communicatively coupled to the first circuit board. Further, the pair of posts are movable axially with respect to the common electro-magnetic interference filter core, radially over-and-under with respect to the common electro-magnetic interference filter core, radially side-by-side with respect to common electro-magnetic interference filter core, or radial diagonal common electro-magnetic interference filter core. It should be appreciated that each strap and/or the EMI core are a ferrite material. In other embodiments, each strap and/or the EMI core are powdered metal.

In other embodiments, the cooling structure is a plurality of fins positioned on the exterior surface of the lower wall such that the lower wall is a heatsink and the plurality of fins form a fluid inlet. A fluid outlet is positioned below the fluid inlet in a system vertical direction. The fluid inlet is for receiving a fluid into the cooling structure and the fluid outlet is for removing the fluid from the cooling structure in an arcuate fluid path. The cooling structure is configured to remove heat generated by the plurality of modules and minimizes recirculation of the fluid that is exhausted from the fluid outlet. That is, the cooling structure in this embodiment is configured to maximize cooling of the plurality of power modules while minimizing the recirculation of warmer exhaust into ambient temperature air.

Further, in this embodiment, the power electronic assembly includes a battery stud assembly extending through a portion of the continuous outer wall and communicatively coupled to the first and second circuit boards. A field connector extending through a portion of the continuous outer wall and communicatively coupled to the first circuit board. A signal connector extending through a portion of the continuous outer wall and communicatively coupled to the first circuit board. The battery stud assembly includes a pair of posts and a common mode choke that circumferentially surrounds and is communicatively coupled to a portion of each post of the pair of posts. Further, each post of the pair of posts include a sleeve configured to provide an electromagnetic interference to each post of the pair of posts. The pair of posts are movable between a plurality of configurations including an over-and-under configuration, a side-by-side configuration, a diagonal configuration, and the like.

As used herein, the term “communicatively coupled” means that coupled components are capable of exchanging data signals with one another such as, for example, electrical signals via a conductive medium or a non-conductive medium, through networks such as via Wi-Fi, Bluetooth, and the like, electromagnetic signals via air, optical signals via optical waveguides, and the like.

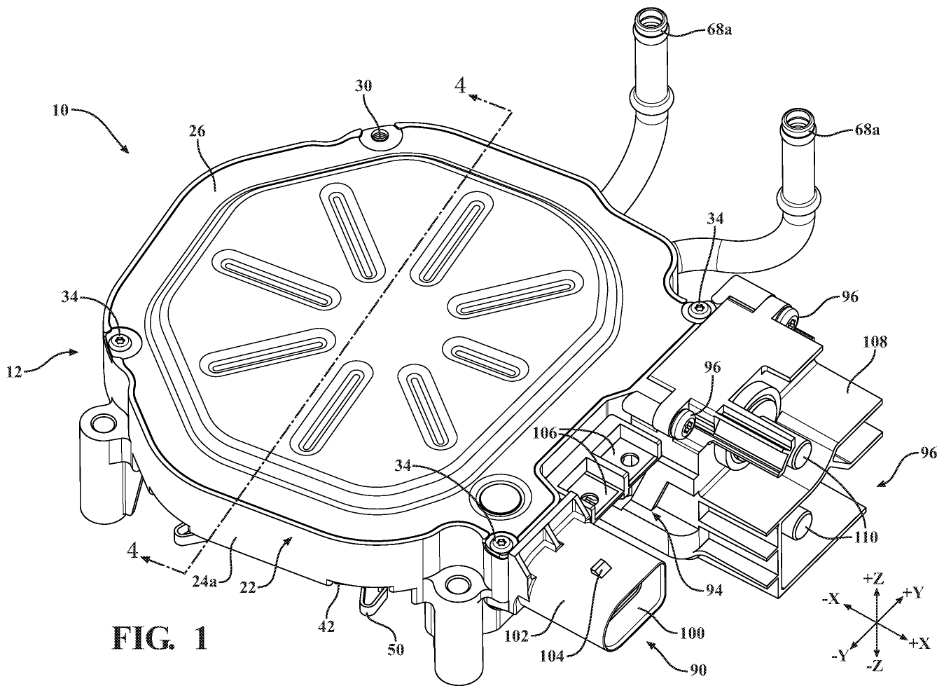

As used herein, the term “system longitudinal direction” refers to the forward-rearward direction of the system (i.e., in a +/−X direction of the coordinate axes depicted in FIG. 1). The term “system lateral direction” refers to the cross-direction (i.e., along the Y axis of the coordinate axes depicted in FIG. 1), and is transverse to the longitudinal direction. The term “system vertical direction” refers to the upward-downward direction of the system (i.e., in the +/−Z direction of the coordinate axes depicted in FIG. 1). As used herein, “above” is defined as generally being towards the positive Z direction of the coordinate axes shown in the drawings. “Below” is defined as generally being towards the negative Z direction of the coordinate axes shown in the drawings.

With reference to FIGS. 1-4, a first example power electronic assembly 10 is schematically depicted. The power electronic assembly 10 includes a housing 12. The housing includes a lower wall 14 having an interior surface 16a and an exterior surface 16b. In some embodiments, the interior surface 16a includes a plurality of cavities 18 arranged in a semicircular pattern around a peripheral edge 20 of the lower wall 14. Further, the housing 12 includes an outer wall 22 that extends from the lower wall 14. In some embodiments, the outer wall 22 is a continuous wall. The outer wall 22 surrounds the lower wall 14 circumferentially, or extends from the peripheral edge 20 of the lower wall 14 such that a lower portion 22a of the outer wall 22 is in contact with the lower wall 14.

The outer wall 22 further includes an interior surface 24a and an exterior surface 24b. A cover 26 abuts an upper surface 22b of the outer wall 22. The cover 26 may be releasably attached to the housing 12 via a plurality of fasteners 28 and corresponding openings 30 in the cover 26. The plurality of fasteners 28 may include a receiving cavity 32 disposed within the outer wall 22 between the interior and exterior surfaces 24a, 24b. In some embodiments, the receiving cavity 32 is a threaded cavity. In other embodiments, the receiving cavity 32 is non-threaded. A fastener 34 may be positioned through the corresponding opening 30 in the cover 26 and into the receiving cavity 32. The fastener 34 may be a screw, a nut and bolt, and the like.

In some embodiments, the housing 12 includes a plurality of curvilinear sections 36 connected together by a plurality of linear sections 38. It should be appreciated that this is non-limiting and the housing 12 may be any shape, such as a square, a rectangle, a hexagon, a circle, and the like.

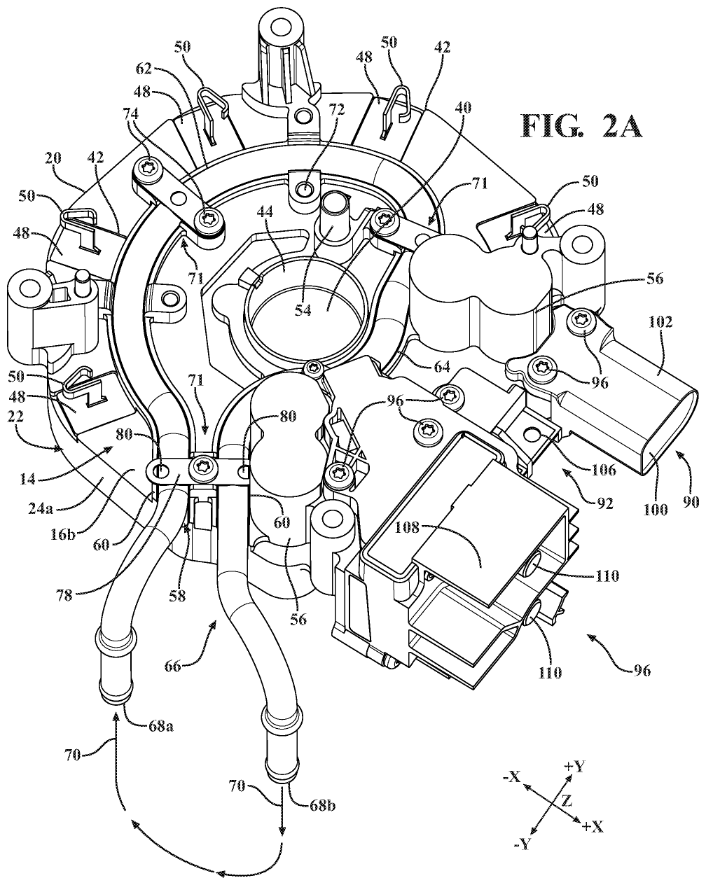

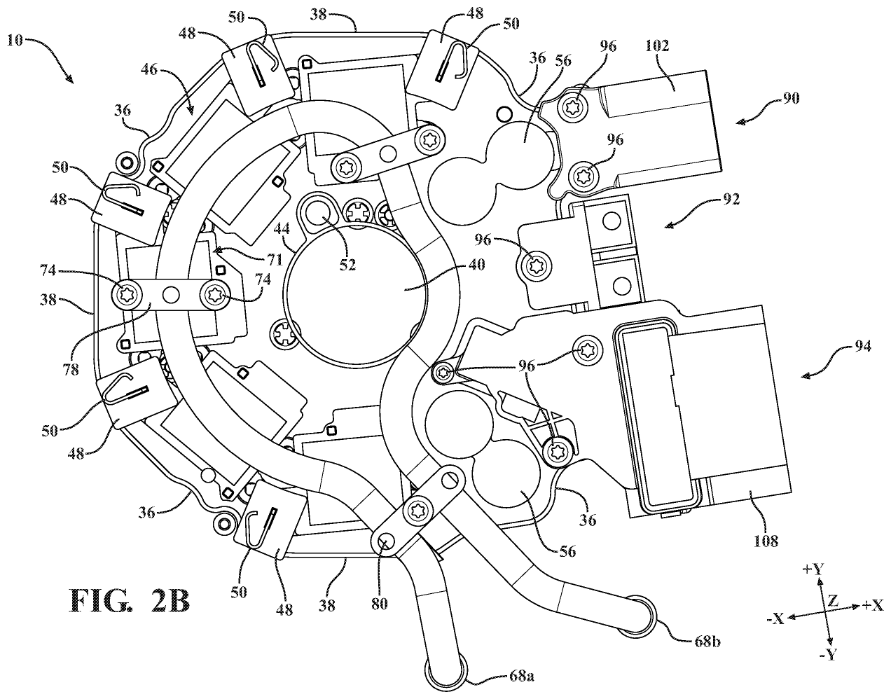

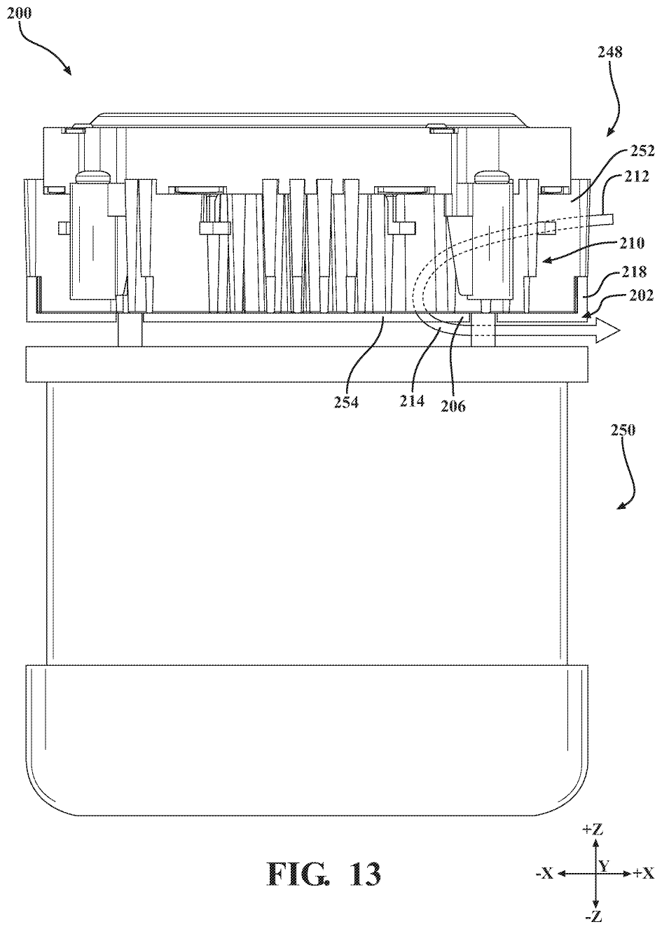

Now referring back to FIGS. 1 and 2A-2B, in some embodiments, the lower wall 14 of the housing 12 further includes an aperture 40 and a plurality of openings 42. The aperture 40 may extend through the lower wall 14 but not the cover 26. The aperture 40 may be circumferentially sounded by an inner wall 44. The aperture 40 may be configured to receive a shaft. For example, a fan shaft of the machine 250 (FIG. 13), a motor shaft, and the like. The plurality of openings 42 may provide access for components, such as phase connections, to extend through the housing 12 to communicatively couple to components within the housing 12, such as the plurality of modules 46 and to components outside of the housing, such as a machine 250 (FIG. 13). Each of the plurality of openings 42 may include a phase crimp housing 48 and a phase crimp 50, in which the phase crimp may be a copper material and the phase crimp housing 48 may be a plastic material, a PEEK material, and the like, as discussed in greater detail herein. The exterior surface 16b of the lower wall 14 may further include a bore 52 configured for a temperature sensor 54. The temperature sensor 54 may be configured to output a signal that corresponds to a temperature of the lower wall 14, a temperature of a space between the lower wall 14 and the cover 26, a combination thereof, and the like. Further, the lower wall 14 may include a plurality of voids 56 that extend from the exterior surface 16b and are open through the interior surface 16a 16b. The plurality of voids 56 are configured for bus capacitors, as described in greater detail herein.

Further, in some embodiments, the exterior surface 16b of the lower wall 14 includes a recess 58. The recess 58 generally has a pair of linear portions 60, an arcuate portion 62 connected to one of the linear portions, and a generally “S” shape 64 that connects to the arcuate portion 62 and the other one of the linear portions 60. The recess 58 is configured to receive a cooling device 66, such as a cooling tube. It is appreciated that the cooling tube 66 is generally the same shape as the recess 58 and that the recess 58 has a depth in the system vertical direction capable of holding the cooling tube 66. Further, as best illustrated in FIG. 2B, it should be appreciated that the recess 58 and the cooling tube 66 follows a path of the plurality of modules 46 arranged on the lower wall 14, as discussed in greater detail herein. That is, the placement of the cooling tube 66 along the exterior surface 16b of the lower wall 14 may optimize the heat transfer from the plurality of modules 46 in contact with the interior surface 16a of the lower wall 14, as discussed in greater detail herein.

The cooling tube 66 includes a fluid inlet 68a and a fluid outlet 68b. The fluid inlet is configured for receiving a cooling fluid 70 into the cooling tube 66 and the fluid outlet 68b is for removing the cooling fluid 70 from the cooling tube 66. In some embodiments, the cooling tube 66 is coupled to the exterior surface 16b of the lower wall 14 within the recess 58 via a plurality of fasteners 71. The plurality of fasteners 71 may be a pair of receiving cavities 72 positioned on each side of the recess 58 and configured to receive a plurality of attachments 74 such as screws, bolt and nuts, hook and loop fasteners, and the like. In some embodiments, an elongated member 78 that includes a pair of apertures 80 may be positioned in contact with the cooling tube 66 and the pair of receiving cavities 72. The elongated member 78 may be configured to retain the cooling tube 66 within the recess 58.

As such, the lower wall 14 may be a heat sink device that may be coupled to a heat generating device, such as the plurality of modules 46, to remove heat and lower the maximum operating temperature of the heat generating device. The cooling fluid 70 may be used to receive heat generated by the heat generating devices by convective thermal transfer, and remove such heat from the heat generating devices. For example, cooling fluid 70 may be directed through the cooling tube 66 to remove heat from the plurality of modules 46. As such, the cooling fluid 70 may be initially introduced into the fluid inlet 68a where the cooling fluid 70 is circulated through the cooling tube 66 to remove heat from the lower wall 14 in contact with the plurality of modules 46. As such, the amount of the cooling fluid 70 and/or the temperature of the cooling fluid 70 circulated at the lower wall 14 may be controlled based on the placement of the cooling tube 66 in the recess 58, the size and diameter of the cooling tube 66, the shape of the cooling tube 66, and the like.

The cooling fluid 70 may be a dielectric cooling fluid, such as, without limitation, R-245fa and HFE-7100. Other dielectric cooling fluids may be utilized. The type of dielectric cooling fluid chosen may depend on the operating temperature of the heat generating devices to be cooled.

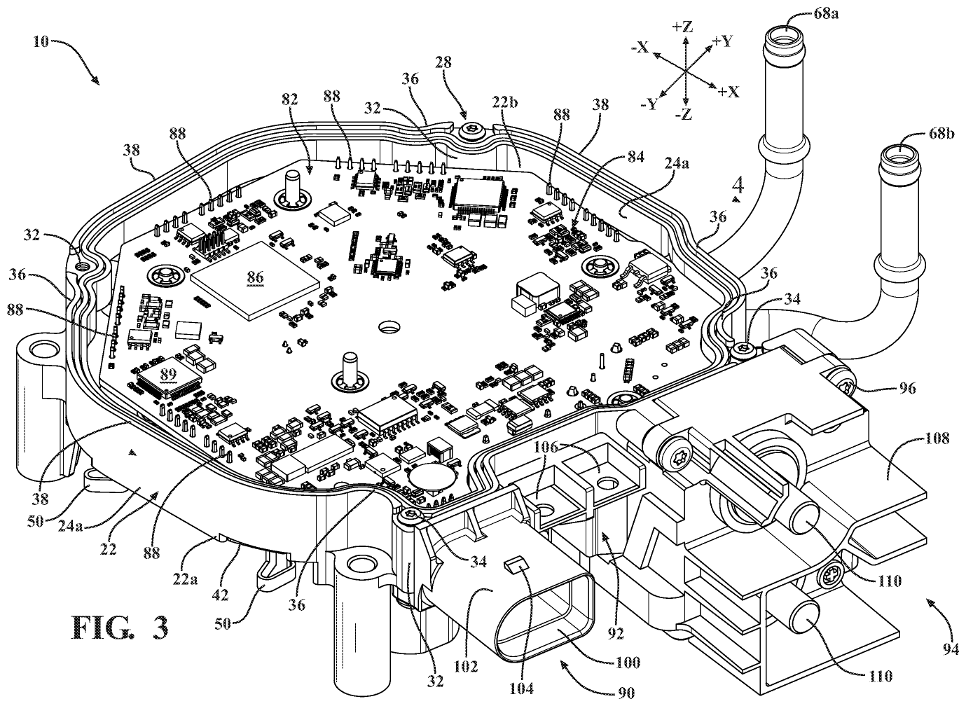

Now referring to FIG. 3, the power electronic assembly 10 is illustrated with the cover 26 removed. The power electronic assembly 10 further includes a first circuit board 82 positioned within the interior surface 24a of the outer wall 22 and within the interior surface 16a of the lower wall 14. In some embodiments, the first circuit board 82 may be a printed circuit board. The first circuit board 82 may be a control board and is communicatively coupled to a plurality of discrete components 84, a processor module 86, at least one gate driver 89, and the like. Each of the plurality of modules 46 (FIG. 2B) are communicatively coupled to the first circuit board 82 via a signal connector terminals 88 extending from each of the plurality of modules 46 (FIG. 2B).

Referring back to FIGS. 1-4, the power electronic assembly 10 further includes a connector receptacle 90, a field connector 92 and a battery stud assembly 94 coupled to the housing 12 via fasteners 96. The connector receptacle 90, the field connector 92 and the battery stud assembly 94 each extend from the exterior surface 24b of the outer wall 22 and are each communicatively coupled to the first circuit board 82. The connector receptacle 90 has a housing 98, that, in some embodiments, is overmolded, and includes a socket 100 and an exterior surface 102 configured to receive a connector. The exterior surface 102 may include a protrusion 104 configured to lock the connector into the socket. In some embodiments, the socket 100 is a 8-pin socket. The socket 100 is configured to communicatively couple at least the first circuit board 82 to the connector to communicatively couple the power electronic assembly 10 to a vehicle.

The field connector 92 includes a pair of receptacles 106 configured to communicatively couple to a brush holder. One of the pair of receptacles 106 is configured to receive a positive voltage while the other one of the pair of receptacles 106 is configured for a negative voltage. It should be appreciated in AC applications, the positive and negative terminals may interchange during operation.

The battery stud assembly 94 includes a housing 108 that, in some embodiments, is overmolded. A pair of posts 110 extend outwardly from the housing 108 and is configured to be communicatively coupled to a 48 volt source, such as those commonly found in hybrid and/or autonomous vehicles. The pair of posts 110 extend outwardly in the system longitudinal direction (i.e., in the +/−X-direction) in a direction away from the exterior surface 24b of the outer wall 22. The position of the pair of posts 110 are adjustable into multiple configurations, as discussed in greater detail herein. Further, the battery stud assembly 94 includes electromagnetic interference protections, as discussed in greater detail herein.

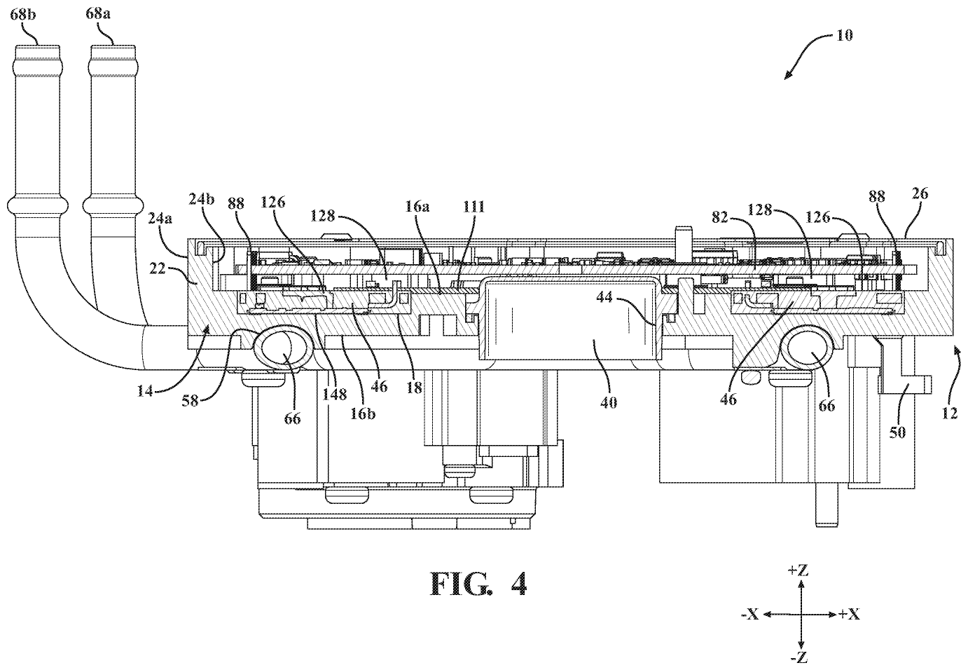

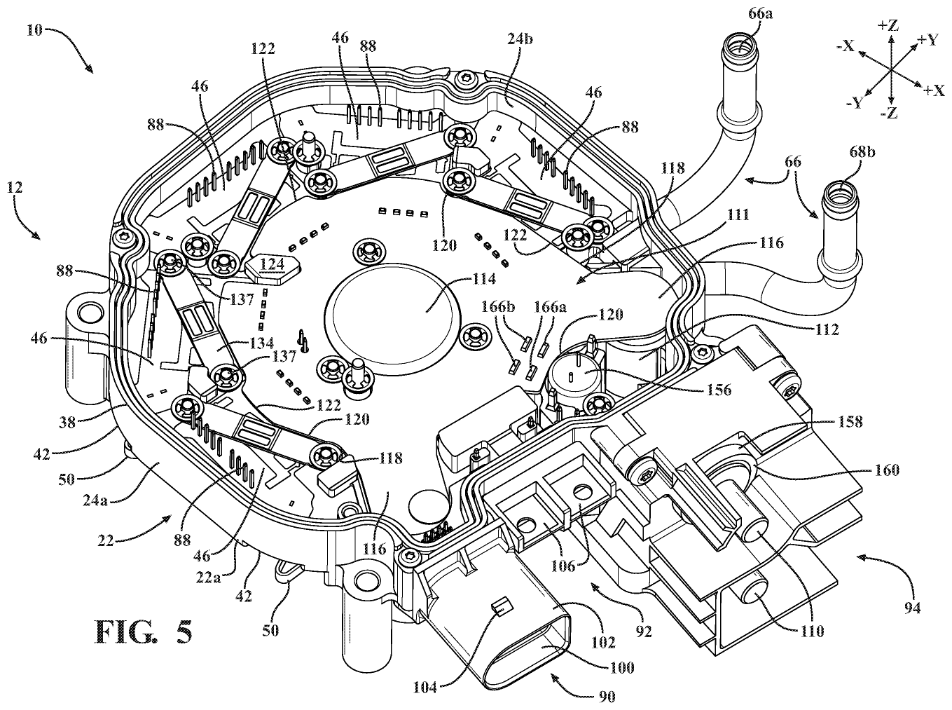

Now referring to FIGS. 4-5 and still referring to FIGS, 1-3, a cross-sectional view of the power electronic assembly taken from line 4-4 will be discussed. The power electronic assembly further includes a second circuit board 111 positioned below the first circuit board 82 in the system vertical direction (i.e., in the +/−Z direction). In some embodiments, the second circuit board 111 is in contact with the interior surface 16a of the lower wall 14. Further, the second circuit board 111 is communicatively coupled to the plurality of modules 46 and to a plurality of busbar capacitors 112. As such, in embodiments, the second circuit board 111 is configured to distribute power between at least the plurality of modules 46, the plurality of busbar capacitors 112, and the like. In some embodiments, the second circuit board 111 is a printed circuit board. The second circuit board 111 may be include a bore 114 that corresponds with the aperture 40 and the inner wall 44 of the housing 12. Further, the second circuit board 111 may include a pair of lobes 116 extending outwardly from a perimeter 118 of the second circuit board 111. Further, the perimeter 118 of the second circuit board 111 may include a plurality of curvilinear segments 120 separated by a plurality of linear segments 122. The second circuit board 111 overlaps at least a portion of each of the plurality of modules 46. Further, the second circuit board 111 includes a raised surface 124. The raised surface aligns with the processor module 86, or is directly beneath the processor module 86 to couple the processor module 86 to the lower wall 14. As such, the raised surface 124 is configured as a cooling pedestal for the processor module 86.

Now referring back to FIGS. 1-5, the plurality of modules 46 are arranged circumferentially with respect to the interior surface 24a of the outer wall 22. That is, the plurality of modules 46 are arranged in a generally semicircular pattern. Each of the plurality of modules 46 are in contact with the interior surface 16a and communicatively coupled to both the first and second circuit boards 82, 111. In some embodiments, each of the plurality of modules 46 are planar with respect to the lower wall 14. In other embodiments, at least one of the plurality of modules 46 are angled or tilted with respect to the lower wall 14. Further, in some embodiments, each of the plurality of modules 46 may be positioned within the corresponding cavity 18 in the lower wall 14 such that an upper surface 126 of each of the plurality of modules 46 is flush to the interior surface 16a of the lower wall 14. As such, it is appreciated that the plurality of modules 46 and the second circuit board 111 may be spaced apart from the first circuit board 82 defining a gap 128 between the second circuit board 111 and the first circuit board 82.

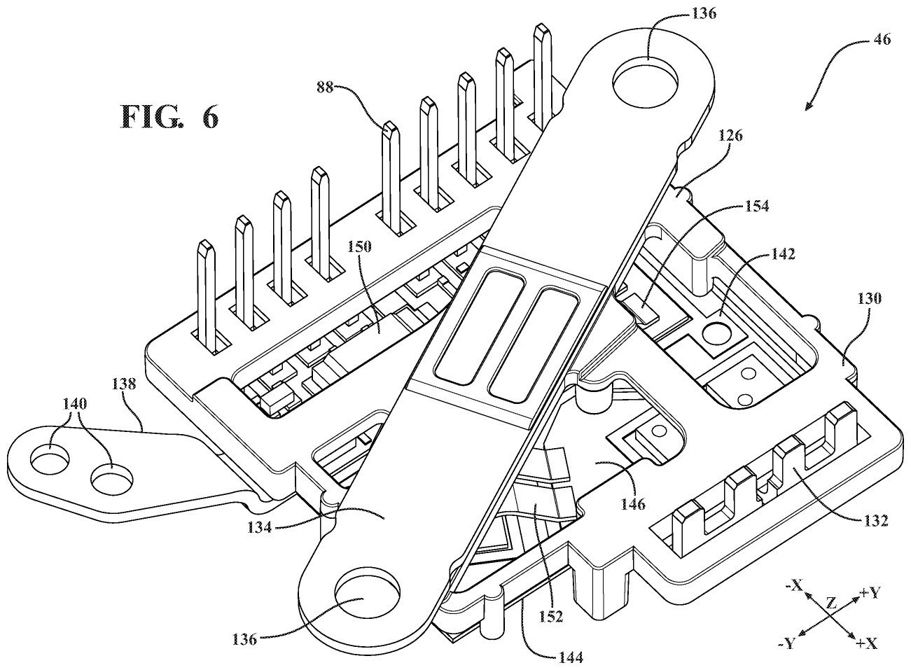

Now referring to FIGS. 5-6, an isolated view of one of the plurality of modules 46 is schematically depicted. In some embodiments, the module 46 is encapsulated in a potting material 130, such as a silicone gel. The module 46 may further include the signal connector terminals 88 and battery leads 132 that extend from the potting material 130 and are configured to communicatively couple to the first and second circuit boards 82, 111 (FIG. 4) respectively. A first elongated member 134 having a pair of bores 136 extends across the upper surface 126 of module 46 and a second elongated member 138 having a pair of bores 140 extends outwardly from the potting material 130. The bores 136 of the first elongated member 134 is configured to receive a fastener 137 such as a screw, a rivet, a bolt and nut, and the like such that the first elongated member is a mounting plate to retain the module 46 in the corresponding cavity 18 (FIG. 4) of the lower wall 14 (FIG. 4). The bores 140 of the second elongated member 138 is configured to receive a fastener such as a tab, a protrusion and the like, of the phase crimp 50 (FIG. 2B) that is coupled to the second circuit board 111 such that the second elongated member 138 is configured as a phase lead frame that is communicatively coupled to a phase component of the voltage.

The module 46 further includes an upper layer 142 and lower layer 144, and a board 146 sandwiched between the upper and lower layers 142, 144. The upper and lower layers 142, 144 may be formed from a copper material and the board 146 may be formed from aluminum. In some embodiments, the module 46 further includes a reinforcement plate 148 in contact with the lower layer 144 and the cavity 18 of the lower wall 14. The module 46 may be configured to provide power and, as such, may further include a shunt 150, ribbon bonds 152, MOSFET dies 154, other discrete components, and the like, that may be communicatively coupled to the board 146 and/or the upper and lower layers 142, 144 to form a half bridge circuit. Further, the signal connector terminals 88 and battery leads 132 may be communicatively coupled the board 146 and/or the upper and lower layers 142, 144.

In other embodiments, the module 46 is overmolded with an epoxy. It is appreciated that in the overmold embodiment, openings are left for ultra-sonic welding of lead frames for connection to a battery plus, battery negative and phase connections. In this embodiment, the lead frames may be constructed from a conductive medium, such as copper. It is also appreciated that the overmold includes apertures to press the direct bonding copper (DBC) during moulding to prevent flash.

It should be appreciated that the module 46 may contain several additional electrical power components, such as a plurality of power semiconductor devices, a plurality of phase current sense resistors, and at least one temperature sensor.

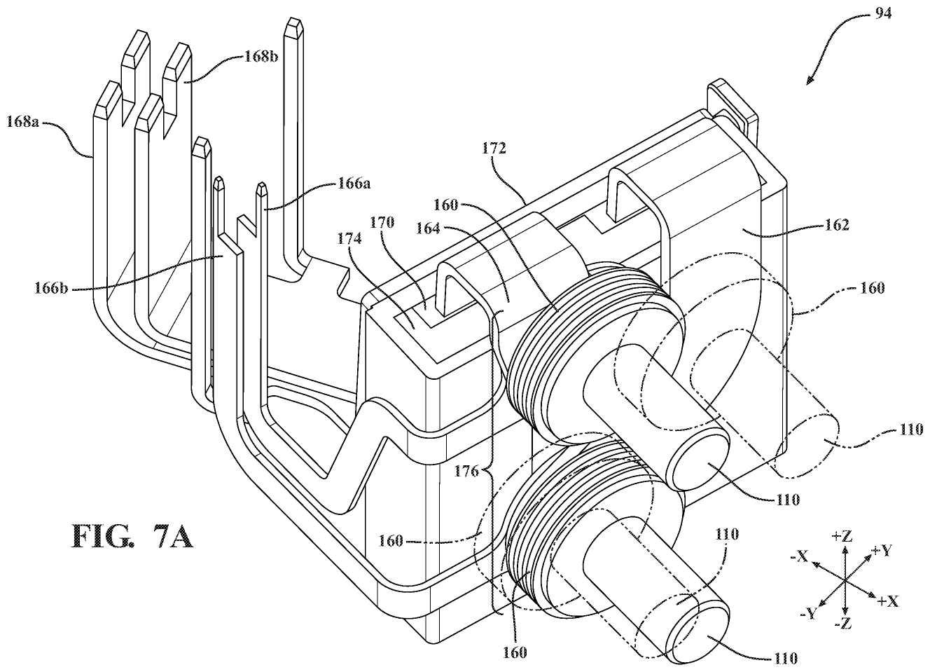

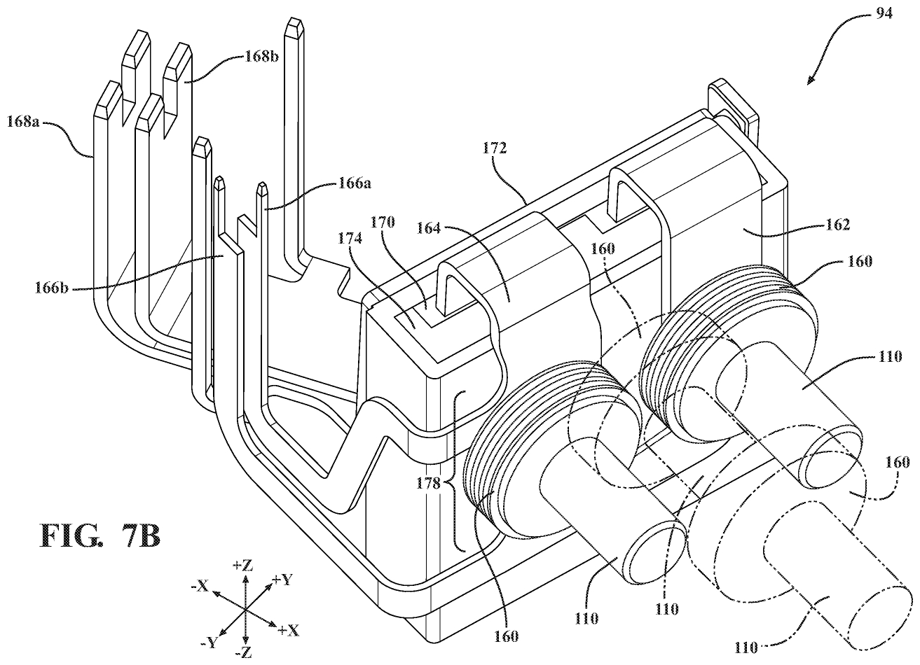

Now referring to FIGS. 7A-7B and still referring to FIGS. 1-5, an isolated view of the battery stud assembly 94 is schematically depicted. The battery stud assembly 94 includes the housing 108 and an electromagnetic interference capacitor 156. The housing 108 may be an overmold configured to encase the components of the battery stud assembly 94, as discussed in greater detail herein. The electromagnetic interference capacitor 156 may be positioned within the interior surface 24a of the outer wall 22 and the interior surface 16a of the lower wall 14 and is communicatively coupled to the first circuit board 82 and other components of the battery stud assembly 94, as described in greater detail herein.

The housing 108 includes a pair of openings 158 configured to receive the pair of posts 110, or elongated members. The pair of posts 110 are spaced apart. In some embodiments, the pair of posts 110 may be, without limitation, M8 studs configured for a 48-volt battery plus terminal and a 48-volt battery negative terminal. It is appreciated that this is non-limiting and the size of each posits may be different than an M8 stud, one may be different, and the like. Each post of the pair of posts 110 further includes a flange 160 that is in contact with a strap 162, 164. Each of the straps 162, 164 are configured to provide electromagnetic interference (EMI). Each strap 162, 164 includes a first end 166a, 166b and a second end 168a, 168b respectively. Both the first end 166a, 166b and the second end 168a, 168b are communicatively coupled to the first and second circuit boards 82, 111.

The battery stud assembly 94 further includes an EMI core 170 and a plate 172, positioned rearward of the pair of posts 110 in the system longitudinal direction. In some embodiments, the EMI core 170 is encapsulated by an EMI housing 174 that may be a potting material and the plate 172 is positioned between the EMI housing and the outer wall 22 of the housing 12. The EMI Core 170 and the EMI housing 174 are positioned between the pair of posts 110 and the plate 172. A portion of each of the straps 162, 164, between the first end 166a, 166b and the second end 1668a, 168b, is disposed within the EMI core 170 and the EMI housing 174 such that the portion is shielded from EMI. That is, a portion of each of the two straps 162, 164 independently passes through the EMI core 170 to filter EMI signals generated at the pair of posts 110, at the first and second circuit boards 82, 111, at the vehicle side and the like. As such, it should be appreciated that the EMI core 170 is a common EMI filter and coupled to each post of the pair of posts 110 via each post having independent straps 162, 164. It should also be appreciated that each strap 162, 164 is generally a pair of U-shape configurations, one at the first end 166a, 166b and the second is formed where the strap enters the EMI core 170 and where the second end 168a, 168b communicatively couples to the second circuit board 111. In embodiments, the second u-shape is configured to cradle the EMI capacitor 156.

Each of the pair of posts 110, the flange 160 and respective strap 162, 164, are configured to be adjusted into a plurality of configurations to mate with the terminals on the vehicle side. The pair of posts 110 may be moved such that each post of the pair of posts 110 is in an under-over configuration 176 (see solid lines of FIG. 7A), a side by side configuration 178 (see solid lines of FIG. 7B), and a diagonal configuration (see dash-dot-dot lines in FIGS. 7A-7B). Further the diagonal configuration may be in both directions. The under-over configuration 176 and side by side configuration 178 may be adjusted axially and radially with respect to the EMI core 170.

Now referring to FIGS. 1-7 the power electronic assembly 10 is configured to provide a stable power supply to various vehicle components, such as the machine, even if an engine of the vehicle is not running (i.e., during advanced stopping, starting, powertrain control, and the like). Further, it should be appreciated that the power electronic assembly described herein provides for a compact design and implementation and is configured to be supported in a wide range of applications due to the adjustment and versatility of the battery stud assembly.

The functionality of the power electronic assembly 10, and in particular, the functionality of the cooling device 66 will now be described. The cooling fluid 70 is initially introduced into the fluid inlet 66a where the cooling fluid 70 is circulated through the cooling tube 66 to remove heat from the plurality of modules 46, the processor module 86, and other components. As such, the amount of the cooling fluid 70 and/or the temperature of the cooling fluid 70 circulated at the plurality of modules 46 and/or electronic components may be controlled based on the sensed temperature, the type of application, the plurality of modules 46, the diameter of the cooling tube 66, and the like.

Due to the placement of the cooling tube 66, it should be appreciated that the cooling fluid 70 may make contact with a portion of the exterior surface 16b of the lower wall 14 via the cooling tube 66. It should also be appreciated that the cooling fluid 70 may be directed in a single path across the exterior surface 16b via the cooling tube 66 or may include more than one cooling tube 66 and/or flow path. The cooling device 66 may be connected to a pump (not shown) such that the cooling fluid 70 may be pumped through the fluid inlet 68a and out of the fluid outlet 68b as described above. In operation, the cooling fluid 70 flowing through the cooling tube 66 may remove heat from one or more heat generating devices thermally coupled to the lower wall 14. A cooling fluid reservoir (not shown) may be fluidly connected to the fluid pump (not shown), the fluid inlet 68a and/or the fluid outlet 68b such that the cooling fluid reservoir (not shown) may house the cooling fluid 70, and the fluid pump (not shown) may pump the cooling fluid 70 through the cooling tube 66. For example, the cooling fluid 70 may be pumped from the cooling fluid reservoir (not shown) into the fluid inlet 68a, through the cooling tube 66 and out of the fluid outlet 68b back into the cooling fluid reservoir (not shown). Further, a secondary heat exchanger (not shown) may remove heat collected by the cooling fluid 70 before the cooling fluid enters the cooling fluid reservoir (not shown). It should be appreciated that the cooling pump, the cooling reservoir, and/or the secondary heat exchange may be integrated with components of the vehicle, such as a radiator and overflow, and the like. As such, the cooling device may operate in conjunction with the components of the vehicle. In other embodiments, some or all of the components of the cooling device 66 may operate independently from the components of the vehicle.

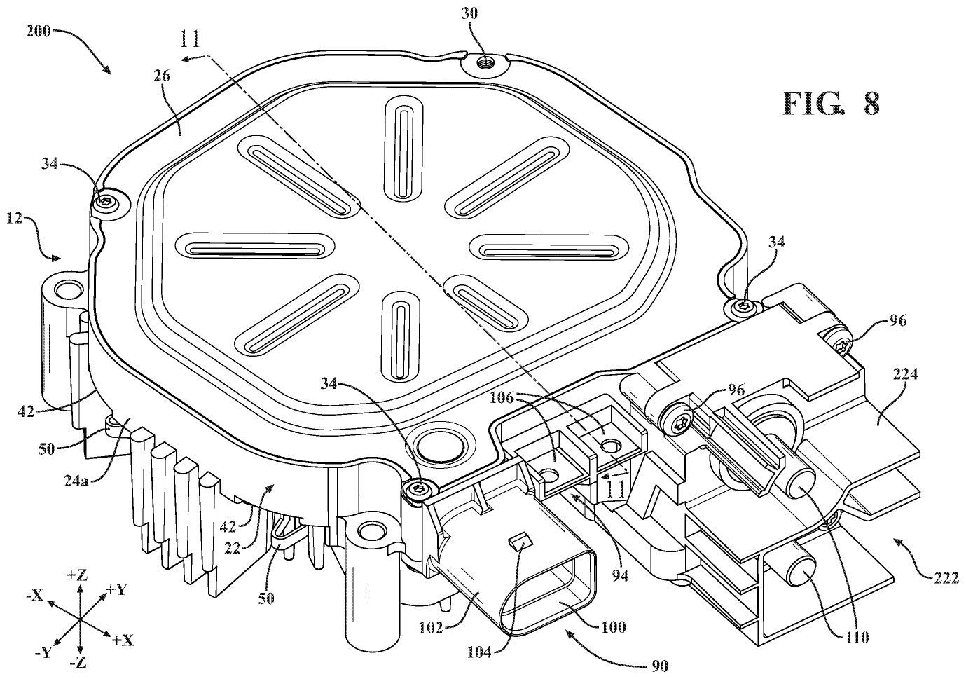

Now referring to FIGS. 8-13, a second embodiment of an example power electronic assembly 200 is illustrated. Except for the differences explicitly noted herein, it should be understood that the power electronic assembly 200 is similar to the first example power electronic assembly 10 described above such that the second example power electronic assembly 200 may be configured and operable just like the first example power electronic assembly 10. Accordingly, identical components are marked with the same reference numerals. It should be understood that any components and operabilities of the second example power electronic assembly 200 that are not explicitly described below may be the same as the components and operabilities of the first example power electronic assembly 10 described above.

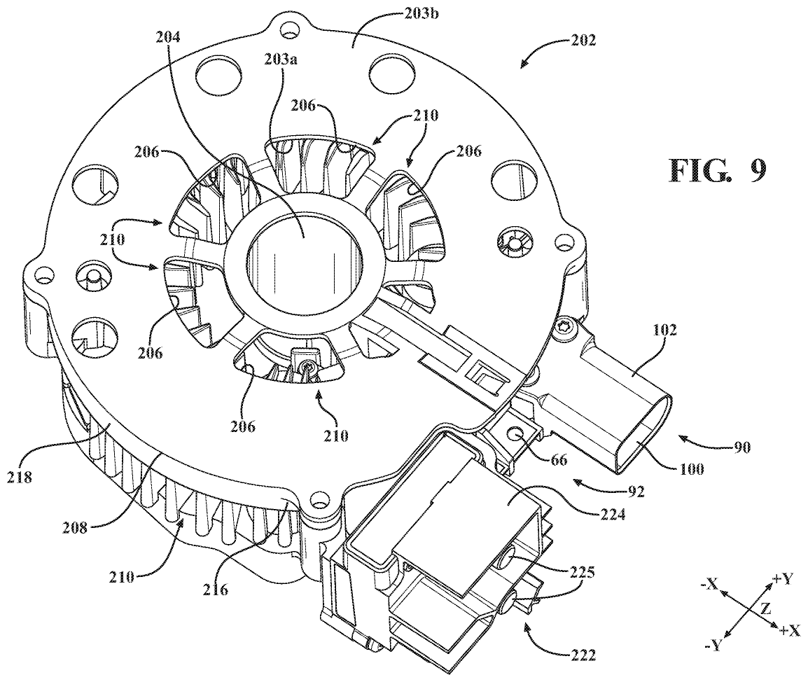

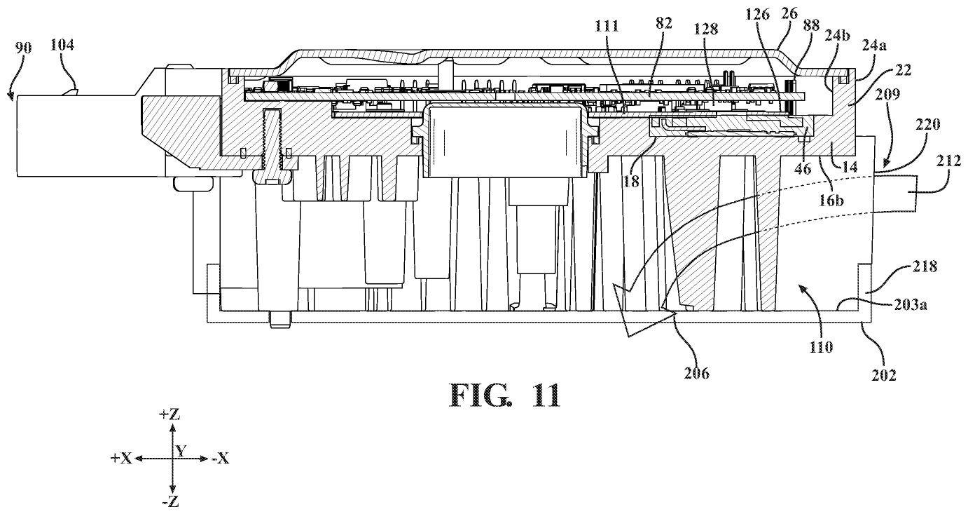

As best shown in FIG. 9, the second example power electronic assembly 200 has a plurality of fins 210 that extend from the exterior surface 16b of the lower wall 14. In some embodiments, each of the plurality of fins 210 may be curvilinear with respect to the exterior surface 16b of the lower wall 14. In other embodiments, only a portion of the plurality of fins 210 may be curvilinear and/or only some of the plurality of fins 210 extend in a curvilinear pattern. Further, in some embodiments, the location of the plurality of fins 210 is configured to direct ambient fluid flow into the area of the lower wall 14 where the plurality of modules 46 are in contact with the lower wall 14. As such, the plurality of fins 210 are a fluid intake 212 (FIG. 11) configured to intake a fluid cooler than the fluid exhausted, as discussed in greater detail herein.

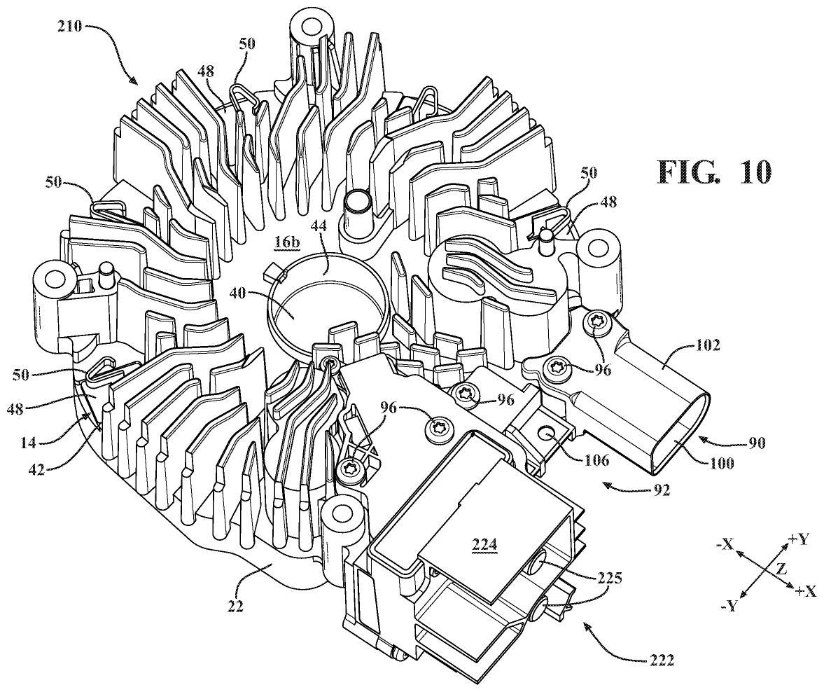

As best shown in FIG. 10, the second example power electronic assembly 200 further includes a guide plate 202 mounted to the exterior surface 16b of the lower wall 14. The guide plate 202 includes an interior surface 203a and an exterior surface 203b. An aperture 204 and a plurality of openings 206 extend through the interior and exterior surfaces 203a, 203b. The aperture 204 of the guide plate 202 is coaxial with the 40 aperture of the lower wall 14. Each of the plurality of openings 206 are spaced apart and may take a plurality of shapes, such as circles, hexagons, rectangular, square, “D” shaped, and the like. The plurality of openings 206 are in fluid communication with the respective plurality of fins 210. As such, the plurality of openings 206 are configured as a fluid exhaust 214 (FIG. 11) such that a fluid flow 209, as depicted in FIG. 11, is an arcuate fluid flow path in shape. That is, the fluid flow, created from an ambient fluid surrounding the plurality of fins 210, may be a curved or a non-linear flow path as opposed to a planar or axial airflow. As such, the ambient fluid enters the plurality of fins 210 at a cooler temperature than the when the fluid flow exits the plurality of openings 206.

Further, the guide plate 202 includes a peripheral edge 208. In some embodiments, a sidewall 216 extends upwardly from at least portions of the peripheral edge 208 in the system vertical direction such that the sidewall forms a baffle 218 covering at least a portion of at least one of the plurality of fins 210. It should be appreciated that the baffle 218 raises the intake fluid position in the system vertical direction while preventing the intake of fluid from a position where warmer is located. That is, the fluid intake is in an upper portion 220 of the plurality of fins 210 and the fluid exhaust is through at least one of the plurality of openings 206 in the guide plate 202 such that the fluid flow path 209 is arcuate in the system vertical direction and curvilinear in the system longitudinal direction and/or system lateral direction depending on the flow of the fluid.

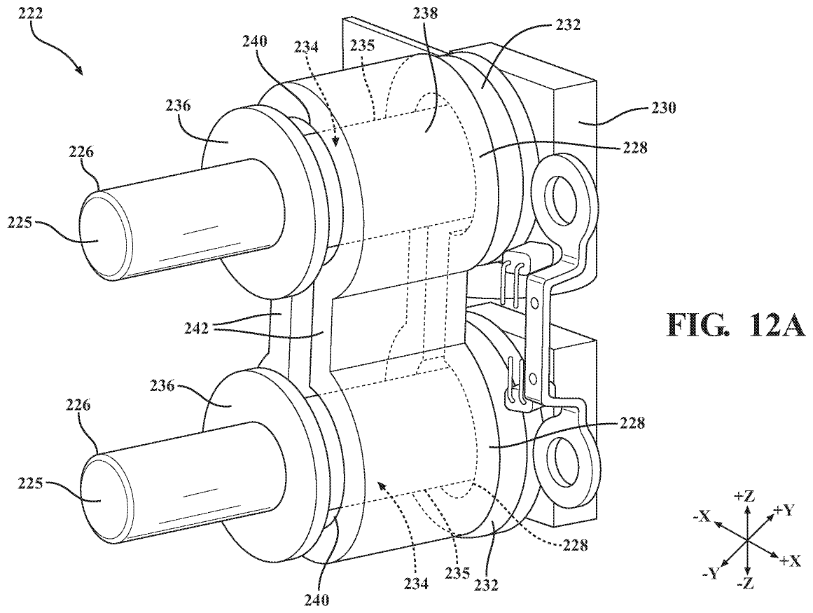

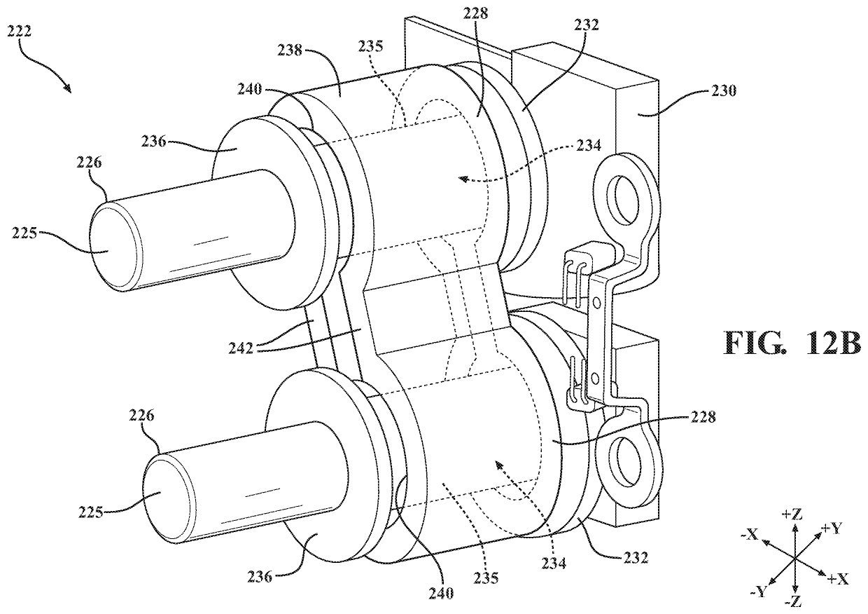

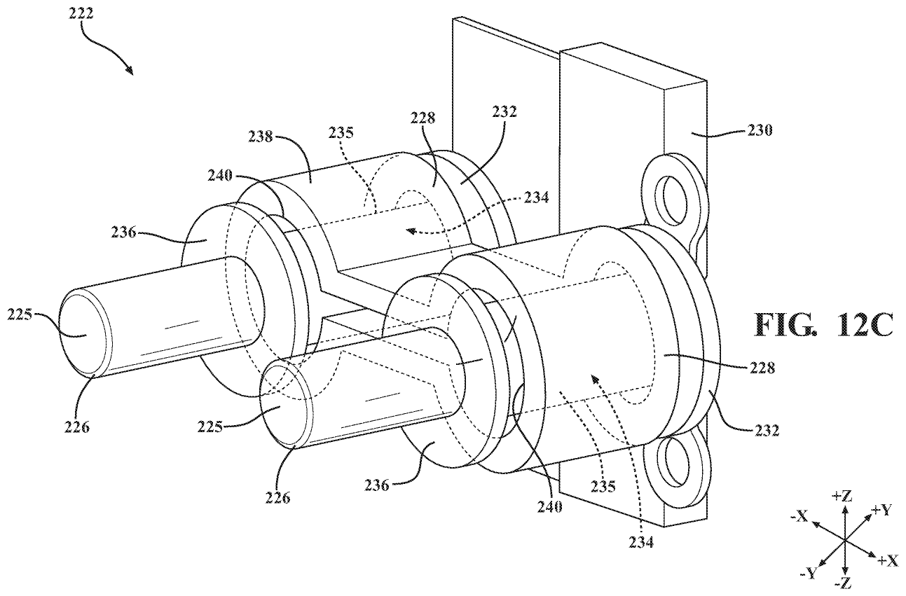

Now referring to FIGS. 12A-12B, and still referring to FIGS. 8-10, a battery stud assembly 222 of the second example power electronic assembly 200 will be described. The battery stud assembly 222 has a housing 224 that may be an overmold and configured to encase the components of the battery stud assembly 222, as discussed in greater detail herein. The battery stud assembly 222 further includes a pair of elongated members, or posts 225. The pair of posts 225 are spaced apart. Each post of the pair of posts 225 includes a first end 226 and a second end 228 opposite the first end 226. The second end 228 terminates into a back wall 230. Each of the pair of posts 225 further include a flange 232 that is in contact with the back wall 230 of the battery stud assembly 222. The pair of posts 225 and the flange 232 may be made of a steel material.

Each of the pair of posts 225 include a sleeve 234 (portions are in phantom indicated with a dot-dot-dot line) that slidably engages with the post 225 and abut the flange 232. Each of the sleeves 234 has a second flange 236 positioned at an opposite end of the flange 232 and the back wall 230 having an exterior surface 235 that covers a portion of the post 225 (i.e. by the sleeve 234) with a smaller diameter between the flanges. A connector 238 having a pair of bores 240 connected by a pair of linear positions 242, generally taking a dog bone shape, is positioned between the flanges 232, 236 and over the smaller diameter exterior surface of the sleeves 234. The connector 238 and the sleeves 234 are each configured for EMI protection generated from the pair of posts 225, the first and second circuit boards 82, 111, the vehicle and the like, as discussed above with respect to the first example power electronic assembly 10. As such, the connector 238 forms a common filter between the individual posts 225. In some embodiments, the connector 238 and each of the sleeves 234 are a ferrite material. In other embodiments, the connector 238 and each of the sleeves 234 are powdered metal.

Each of the pair of posts 225, the flange 232, the respective sleeve 234 and the connector 238 is configured to be adjusted into a plurality of configurations to mate with the terminals on the vehicle side. The pair of posts 225 may be moved such that each post is in an under-over configuration (as shown in FIG. 12a), a side by side configuration (as shown in FIG. 12C), and a diagonal configuration (as shown in FIG. 12b). Further, the diagonal configuration may be in both directions. The under-over configuration and side by side configuration may be adjusted axially and radially with respect to the outer wall 22.

It is understood that the battery stud assembly 94 (FIGS. 7A-7B) may be used in place of the battery stud assembly 222 in the second example power electronic assembly 200. That is, the battery stud assembly 94 (FIGS. 7A-7B)may be communicatively coupled to the components of the second example power electronic assembly 200 in the same manner as described above with respect to the first example power electronic assembly 10 (FIG. 1). It is understand that the battery stud assembly 94 (FIGS. 7A-7B), including the electromagnetic interference capacitor 156 (FIGS. 7A-7B), the straps 162, 164 (FIGS. 7A-7B), the EMI core 170 (FIGS. 7A-7B), the plate 172 (FIGS. 7A-7B), the pair of posts 110 (FIGS. 7A-7B), and the EMI housing 174 (FIGS. 7A-7B) are identical and operate as described above with respect to the first example power electronic assembly 10 (FIG. 1). Further, it is appreciated that the pair of posts 110 (FIGS. 7A-7B), the flange 160 (FIGS. 7A-7B) and respective straps 162, 164 (FIGS. 7A-7B) are configured to be adjusted into a plurality of configurations as discussed with respect to the first example power electronic assembly 10 (FIG. 1). As such, it should be understood that each and every component of the battery stud assembly 94 (FIGS. 7A-7B) may be integrated into the second example power electronic assembly 200.

It should also be appreciated that the battery stud assembly 222 of the second example power electronic assembly 200 may replace the battery stud assembly 94 (FIGS. 7A-7B) in the example power electronic assembly 10 (FIG. 1) in the same manner as described above. As such, the battery stud assembly 94 (FIGS. 7A-7B) and the battery stud assembly 222 are interchangeable between the first example power electronic assembly 10 (FIG. 1) and the second example power electronic assembly 200.

Now referring to FIG. 13, an airflow diagram 248 of the second example power electronic assembly 200 coupled to the machine 250, such as a belt starter generator machine. As illustrated, the baffle 218 prevents fluid intake from occurring anywhere but in an upper portion of the plurality of fins 210. The fluid flow exhausts through at least one of corresponding opening of the plurality of openings 206 creating a fluid outlet 254. It should be appreciated that in operation, the machine 250 and/or the components of second example power electronic assembly produces an exhaust fluid much hotter fluid than the optimal intake fluid. As such, the ambient fluid is brought into the intake fluid, through a fluid inlet 252 in an area away from the exhausted fluid. The cooler temperature fluid causes the temperature of the lower wall 14, the plurality of fins 210, the plurality of modules 46 and the like to decrease the current operating temperature. As such, it should be appreciated that the current embodiments reduce and/or prevent recirculation of the exhaust of the machine and/or of the fluid flow to enter the fluid intake.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

What is claimed is:

1. A power electronic assembly comprising:
a housing having a lower wall and an outer wall that circumferentially surrounds the lower wall, the lower wall having an interior surface and an opposite exterior surface;
a plurality of modules in contact with the interior surface of the lower wall, wherein the lower wall is a heatsink configured to assist in removing heat generated by the plurality of modules;
a first circuit board positioned above the plurality of modules in a system vertical direction and communicatively coupled to the plurality of modules;
a second circuit board positioned between the plurality of modules and the first circuit board; and
a cooling structure provided on the exterior surface of the lower wall to cool the heatsink.

2. The power electronic assembly of claim 1, wherein the cooling structure further comprises:
a fluid inlet; and
a fluid outlet, wherein the fluid inlet is for receiving a cooling fluid into the cooling structure and the fluid outlet is for removing the cooling fluid from the cooling structure,
wherein the cooling fluid removes heat generated by the plurality of modules.

3. The power electronic assembly of claim 2 further comprising:
a battery stud assembly extending through a portion of the outer wall and communicatively coupled to the first and second circuit boards.

4. The power electronic assembly of claim 3, wherein the battery stud assembly further comprises:
a pair of posts,
a pair of straps are independently coupled to a respective one of the pair of posts, and
a common filter is coupled to each of the pair of straps,
wherein each one of the pair of straps and the common filter are configured to eliminate electro-magnetic interference.

5. The power electronic assembly of claim 4, wherein the pair of posts are movable between a plurality of configurations, the plurality of configurations are selected from the group of over-and-under with respect to the common filter, side-by-side with respect to the common filter, or diagonal with respect to the common filter.

6. The power electronic assembly of claim 4, wherein the common filter and the pair of straps are a ferrite material.

7. The power electronic assembly of claim 1, wherein the cooling structure further comprises:
a plurality of fins forming a fluid inlet; and
a fluid outlet positioned below the fluid inlet in the system vertical direction, wherein the fluid inlet is for receiving a fluid into the cooling structure and the fluid outlet is for removing the fluid from the cooling structure in an arcuate fluid path,
wherein the fluid removes heat generated by the plurality of modules.

8. The power electronic assembly of claim 7 further comprising:
a battery stud assembly extending through a portion of the outer wall and communicatively coupled to the first and second circuit boards.

9. The power electronic assembly of claim 8, wherein the battery stud assembly further comprises:
a rear wall,
a pair of posts extending from the rear wall; and
a pair of sleeves having a flange and a bore, the bore having an inner diameter and an exterior surface, each bore of the pair of sleeves configured to slidably engage with each respectively posts of the pair of posts,
wherein each of the pair of sleeves is a ferrite material and are configured for electro-magnetic interference.

10. The power electronic assembly of claim 9, wherein the battery stud assembly further comprises:
a choke having a pair of apertures configured to circumferentially surround and communicatively couple to a portion of each the pair of sleeves such that the choke is common between each of the pair of sleeves,
wherein the choke is a ferrite material and is configured for electro-magnetic interference.

11. The power electronic assembly of claim 9, wherein the pair of posts are movable between a plurality of configurations, the plurality of configurations are selected from the group of axially with respect to the rear wall, radially over-and-under with respect to the rear wall, radially side-by-side with respect to the rear wall, or radially diagonal with respect to the rear wall.

12. The power electronic assembly of claim 7, wherein the plurality of fins are arranged in a curvilinear orientation with respect to the lower wall.

13. The power electronic assembly of claim 1, wherein each of the plurality of modules is overmolded with a silicone gel.

14. The power electronic assembly of claim 1, wherein the first circuit board is a control circuit board communicatively coupled to a processor module.

15. The power electronic assembly of claim 1, wherein the second circuit board is communicatively to the plurality of modules and to a plurality of busbar capacitors.

16. A power electronic assembly comprising:
a housing having a lower wall and an outer wall that circumferentially surrounds the lower wall, the lower wall having an interior surface and an opposite exterior surface;
a plurality of modules in contact with the interior surface of the lower wall;
a first circuit board positioned above the plurality of modules in a system vertical direction and communicatively coupled to the plurality of modules;
a battery stud assembly extending through a portion of the outer wall and communicatively coupled to the first circuit board, the battery stud assembly comprises:
a pair of posts,
a pair of straps are independently coupled to a respective one of the pair of posts, and
a common filter is coupled to each of the pair of straps,
wherein each one of the pair of straps and the common filter are configured to eliminate electro-magnetic interference.

17. The power electronic assembly of claim 16, wherein the common filter and the pair of straps are a ferrite material.

18. The power electronic assembly of claim 16, wherein the pair of posts are movable between a plurality of configurations, the plurality of configurations are selected from the group of over-and-under with respect to the common filter, side-by-side with respect to the common filter, or diagonal with respect to the common filter.

19. A power electronic assembly comprising:
a housing having a lower wall and an outer wall that circumferentially surrounds the lower wall, the lower wall having an interior surface and an opposite exterior surface;
a plurality of modules in contact with the interior surface of the lower wall;
a first circuit board positioned above the plurality of modules in a system vertical direction and communicatively coupled to the plurality of modules;
a second circuit board positioned between the plurality of modules and the first circuit board; and
a cooling tube comprising:
a fluid inlet; and
a fluid outlet, wherein the fluid inlet is for receiving a cooling fluid into the cooling tube and the fluid outlet is for removing the cooling fluid from the cooling tube,
wherein the cooling fluid removes heat generated by the plurality of modules.

20. The power electronic assembly of claim 19, further comprising:
a battery stud assembly extending through a portion of the outer wall and communicatively coupled to the first and second circuit boards, the battery stud assembly comprises:
a pair of posts,
a pair of straps are independently coupled to a respective one of the pair of posts, and
a common filter is coupled to each of the pair of straps,
wherein each one of the pair of straps and the common filter are configured to eliminate electro-magnetic interference.
